(19) United States
(12) Patent Application Publication
(10) Pub. No.: US 2004/0253754 A1
(43) Pub. Date: Dec. 16, 2004

(54) System and method for testing a semiconductor chip

(75) Inventors: Wenjun Zhuang, Singapore (SG); Rajendra Patrikar, Singapore (SG)

Correspondence Address: MARTINE & PENILLA, LLP, 710 LAKEWAY DRIVE, SUITE 170, SUNNYVALE, CA, 94085, US

(73) Assignee: AGENCY FOR SCIENCE TECHNOLOGY AND RESEARCH

(21) Appl. No.: 10/463,564

(22) Filed: Jun. 16, 2003

(51) Int. Cl. H01L 21/66; G01R 31/26

(52) U.S. Cl. 438/18

(57) ABSTRACT

A method for testing a semiconductor chip is provided. The method begins by selecting a sampling circuit having an ideal supply current. A test circuit is provided by fabricating the sampling circuit onto the semiconductor chip. After fabrication has been completed, a test supply current is measured from the test circuit. The test supply current is then compared with the ideal supply current to determine whether there is a defect in the chip as well as to identify any such defect.

### BACKGROUND OF THE INVENTION

1. Field of the Invention

The present invention relates generally to the testing of semiconductor chips. More particularly, the present invention relates to a system and method for detecting defects in semiconductor chips before packaging.

2. Description of the Related Art

The semiconductor manufacturing process is typically separated into four stages: wafer preparation, wafer fabrication, wafer sorting (electrical testing), and packaging. Testing is an integral part of semiconductor chip fabrication not only during wafer sort, but also after packaging. Examples of testing applications include verifying a new semiconductor chip design or fabrication process, identifying working semiconductor chips before packaging, characterizing the electrical parameters of a device or circuit, and determining the reliability of a semiconductor chip.

While the semiconductor industry has observed extremely rapid developments in the manufacturing stages, testing and packaging technologies have failed to advance as rapidly, particularly in the area of cost reduction. As semiconductor chips become more complex, space between conductive lines decreases. Accordingly, testing of the chips has become more difficult and will continue becoming even more challenging because fault coverage is a function of time and area. Not only is the number of circuits that must be tested growing, accessibility to the circuits is decreasing at the same time.

As noted above, testing occurs before and after packaging. If a fatal defect is detected in a chip, it is usually discarded, wasting the entire manufacturing process. Even worse, if such a defect is detected after packaging (i.e. reliability testing), the manufacturer incurs another significant loss since packaging is estimated to be about 20-25% of the total manufacturing cost. Accordingly, if fatal defects can be detected before packaging, a tremendous amount of time and money can be saved.

One example of a conventional testing method is quiescent current (I_{DDQ}) testing. I_{DDQ} testing is based on the premise that complementary metal-oxide semiconductor (CMOS) circuits consume very little current while in the quiescent state. Faults may therefore be detected based on changes in the quiescent current, particularly because the changes caused by defects are of much greater magnitude than that of a normal I_{DDQ}.

Unfortunately, quiescent current testing has several limitations. For example, I_{DDQ} testing can be applied to digital circuits but not to analog circuits or mixed-signal circuits with both analog and digital circuitry. In addition, because of the rapid shrinking of semiconductor components and decreasing line densities, accessibility to test circuits is also decreasing. For example, researchers are currently developing System on Chip (SoC) technology, in which all necessary circuits and components for a system are located on a single chip. Accordingly, future advances in circuit design will continue to decrease accessibility of the circuits to testing.

Another problem with I_{DDQ} testing is that reductions in semiconductor chip size and corresponding increases in the number of transistors integrated on a semiconductor chip have led to an increase in leakage currents, making it difficult to differentiate between defective and non-defective quiescent currents. Instead, the quiescent current is often obscured by background noise. In addition, I_{DDQ} testing is not able to detect open type faults because such faults cause negligible change to quiescent currents leaving a large number of defects undetected. Therefore, I_{DDQ} testing is no longer adequate to satisfy the quality and reliability requirements for modern semiconductor chip applications.

In view of the foregoing, it is desirable to have a system and method for testing a semiconductor chip that is resistant to background noise and can be applied to both analog and digital circuits. It is also desirable to have a comprehensive system and method for testing a semiconductor chip, where the testing is done before packaging to reduce both the cost of testing and the cost of a discarded defective chip.

### SUMMARY OF THE INVENTION

The present invention fills these needs by providing a have a system and method for testing a semiconductor chip. It should be appreciated that the present invention can be implemented in numerous ways, including as a process, an apparatus, a system, a device or a method. Several inventive embodiments of the present invention are described below.

In one embodiment of the present invention, a method for testing a semiconductor chip is provided. The method begins by selecting a sampling circuit having an ideal supply current. A test circuit is provided by fabricating the sampling circuit onto the semiconductor chip. After fabrication has been completed, a test supply current is measured from the test circuit. The test supply current is then compared with the ideal supply current to determine whether there is a defect in the chip as well as to identify any such defect.

In another embodiment of the present invention, a semiconductor chip testing system is provided. The system includes a sensor to measure a supply current from a test circuit on the semiconductor chip. The system also includes a sampling circuit library to store a number of sampling circuits. A processor is coupled between the sensor and the library. The processor compares the supply current with an ideal supply current from a selected sampling circuit to determine whether there is a defect in the chip.

Other aspects and advantages of the invention will become apparent from the following detailed description, taken in conjunction with the accompanying drawings, illustrating by way of example the principles of the invention.

### BRIEF DESCRIPTION OF THE DRAWINGS

The present invention will be readily understood by the following detailed description in conjunction with the accompanying drawings. To facilitate this description, like reference numerals designate like structural elements.

FIG. 1 illustrates a system for testing a semiconductor chip on a semiconductor wafer in accordance with one embodiment of the present invention.

FIG. 2 illustrates a test circuit for detecting a transistor defect in accordance with one embodiment of the present invention.

FIG. 3 illustrates an ideal current signature of the test circuit in FIG. 2 in accordance with one embodiment of the present invention.

FIG. 4 illustrates a current signature of the test circuit in FIG. 2 in accordance with one embodiment of the present invention.

FIG. 5 illustrates a current signature of the test circuit in FIG. 2 in accordance with one embodiment of the present invention.

FIG. 6 illustrates a current signature of the test circuit in FIG. 2 in accordance with one embodiment of the present invention.

FIG. 7 illustrates a test circuit for detecting a defect in a complementary metal-oxide semiconductor (CMOS) operational-amplifier circuit in accordance with one embodiment of the present invention.

FIG. 8 illustrates an ideal current signature of the test circuit in FIG. 7 in accordance with one embodiment of the present invention.

FIG. 9 illustrates a current signature of the test circuit in FIG. 7 in accordance with one embodiment of the present invention.

FIG. 10 illustrates a current signature of the test circuit in FIG. 7 in accordance with one embodiment of the present invention.

FIG. 11 illustrates a current signature of the test circuit in FIG. 7 in accordance with one embodiment of the present invention.

FIG. 12 illustrates a current signature of the test circuit in FIG. 7 in accordance with one embodiment of the present invention.

FIG. 13 illustrates a system for testing a semiconductor chip on a semiconductor wafer in accordance with another embodiment of the present invention.

FIG. 14 illustrates a method for testing a semiconductor chip on a semiconductor wafer in accordance with yet another embodiment of the present invention.

### DETAILED DESCRIPTION OF THE PREFERRED EMBODIMENTS

A system and method for testing a semiconductor chip are provided. In the following description, numerous specific details are set forth in order to provide a thorough understanding of the present invention. It will be understood, however, to one skilled in the art, that the present invention may be practiced without some or all of these specific details. In other instances, well known process operations have not been described in detail in order not to unnecessarily obscure the present invention.

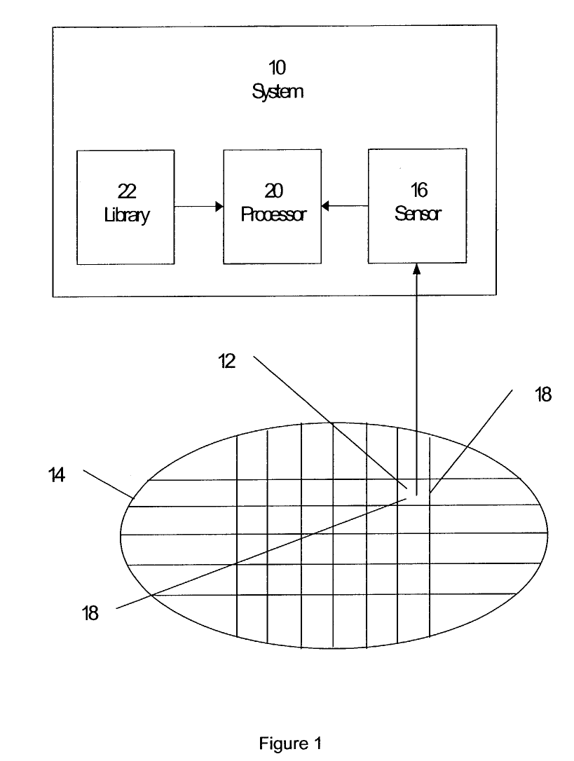

FIG. 1 illustrates a system 10 for testing a semiconductor chip 12 on a semiconductor wafer 14 in accordance with one embodiment of the present invention. System 10 includes a sensor 16 coupled to a test circuit 18 formed on semiconductor wafer 14. Test circuit 18 may be integrated into semiconductor chip 12 on semiconductor wafer 14. Alternatively, test circuit 18 may be fabricated along a scribe line of semiconductor chip 12. A processor 20 is coupled to sensor 16 and a library 22, which includes a number of sampling circuit designs.

Before semiconductor wafer 14 is fabricated, a sampling circuit is chosen from library 22 to use as test circuit 18. After fabrication, a supply current may then be measured from test circuit 18 by sensor 16. The supply current, which is measured without regard to its specific state, provides a current signature to characterise the function and performance of test circuit 18. A processor 20 compares the current signature from sensor 16 with an ideal current signature from the chosen sampling circuit from library 22 to determine whether a defect is present in semiconductor chip 12.

Because defects affect the level of supply current drawn by semiconductor chips, a defect in semiconductor chip 12 is detected if the current signature of test circuit 18 differs from the ideal current signature. For example, a bridge or short that increases the supply current drawn, will be clearly reflected by a current signature that differs from the ideal current signature. The same is true in the case of an open circuit defect, which draws a decreased supply current.

Because the supply current drawn by test circuit 18 is very small, typically in a range of about 0.01 microamperes (μA) to about 10 μA, sensor 16 may be designed to be very responsive to changes in the measured variables and therefore extremely sensitive to defects. In addition to measuring the supply current, sensor 16 may be used to measure other variables such as a frequency performance of test circuit 18. Frequency performance may be useful to identify the reliability signature of the supply current as described below.

In addition to detecting defects in semiconductor chip 12, processor 20 may also be used to identify a specific type of defect present in the chip and to determine a severity of the defect. The current signature I_{DD} of test circuit 18 is expressed by the following equation:

I_{DD}=ƒ(I, d₁, d₂, . . . dₙ) (1)

where I represents an ideal supply current, and d₁, d₂, . . . dₙ represent additional currents drawn as a result of defects 1, 2, . . . n, respectively. Equation (1) may be separated into portions of the current caused by defects. For example, I_{DD} may be separated using deconvolution methods such as Fast Fourier Transform (FFT) and wavelet analysis. The current signature of the individual components as shown in the following equation:

I_{DD}=F(I)+F(d₁)+F(d₂) . . . +F(dₙ) (2)

where F(I) represents an ideal current signature, and F(d₁), F(d₂), . . . F(dₙ) represent the current signatures of defects 1, 2, . . . n, respectively.

F(d₁), F(d₂), . . . F(dₙ) are then matched with a plurality of fault models stored in library 22 to determine the identity and severity of defects 1, 2, . . . n. The fault models, which simulate an electrical impact of a defect, are modeled from SPICE (Simulated Program with Integrated Circuit Emphasis) simulations and Artificial Neural Network (ANN) algorithms using experimental data obtained during the fabrication phase of semiconductor chip 12.

Because it is possible that test circuit 18 draws the same level of supply current for different defects or combinations of defects, semiconductor chip 12 is preferably fabricated with additional test circuits formed from other sampling circuit designs for a more accurate identification of the types of defects detected. Library 22 stores a plurality of ideal current signatures, each of which is specific to a sampling circuit. As with the fault models, the ideal current signatures are modeled from SPICE simulations and Artificial Neural Network (ANN) algorithms using experimental data obtained during the fabrication phase of semiconductor chip 12.

Examples of sampling circuits and corresponding ideal current signatures, as well as measured test supply current signatures are described in greater detail below. To avoid confusion, the circuits described will be referred to generically as test circuits, although since test circuits are fabricated from sampling circuit designs, both may be represented.

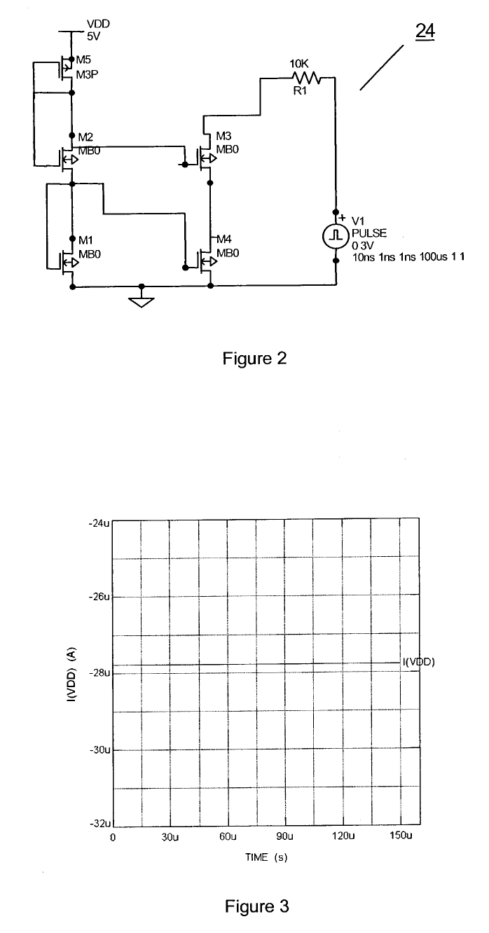

FIG. 2 illustrates a test circuit 24 for detecting a transistor defect in accordance with one embodiment of the present invention. A pulsed voltage is applied to test circuit 24. Test circuit 24 may be used to detect transistor defects such as gate oxide shorts and other imperfections that may cause harm performance or even cause a chip failure. FIG. 3 illustrates an ideal current signature for test circuit 24 in accordance with one embodiment of the present invention. The ideal current signature, obtained by plotting the ideal supply current drawn by a defect-free test circuit as a function of time over a single pulse duration, indicates that the supply current drawn by test circuit 24 should remain constant throughout the pulse duration in the absence of a defect.

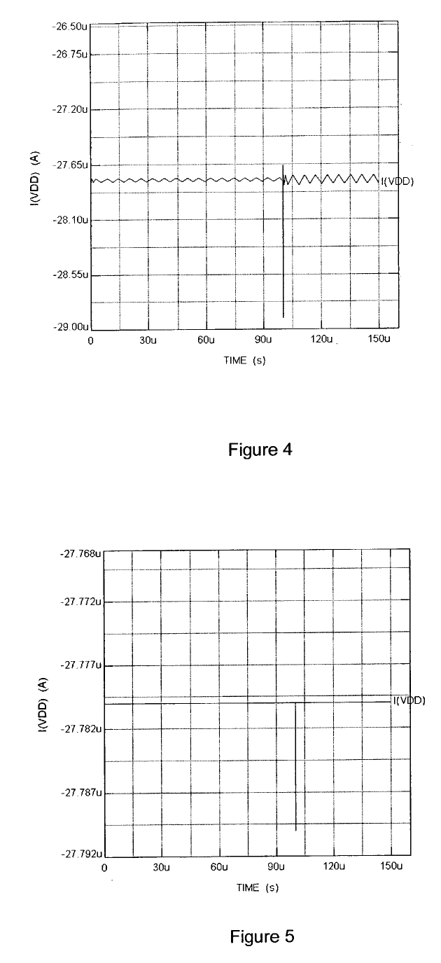

In contrast, FIGS. 4 to 7 illustrate additional examples of current signatures of test circuit 24 in accordance with one embodiment of the present invention. The current signatures were obtained by plotting the supply current drawn by a defective test circuit as a function of time over a single pulse duration.

FIG. 4 illustrates a current signature of test circuit 24 with an overlap capacitance of 1 femto farad (fF) in each of the NMOS ( type metal-oxide semiconductor) transistors in test circuit 24. The overlap capacitance is a result of gate material from the transistor, which is extended over the source and drain regions and must be maintained within a prescribed range for optimal performance. For example, it is known that having a high overlap capacitance slows the performance of the transistor.

A comparison between the current signature and the ideal current signature reveals that the overlap capacitance in the NMOS transistors causes oscillations in the supply current drawn as well as a spike in its current signature. This result shows that comparing the supply current signature of test circuit 24 to the ideal current signature is effective to detect not only the undesired additional capacitance, but other defects as well, such as gate oxide shorts.

FIG. 5 illustrates a current signature of test circuit 24 with multiple defects, namely, an overlap capacitance of 1 fF in the NMOS transistors and a gate to substrate short of 100 kilo-ohms (kΩ). In addition to a transient at 100 microseconds (μs) and a spike, the current signature also shows an increase in the value of the supply current drawn by about 500 nA, which results from the gate to substrate short.

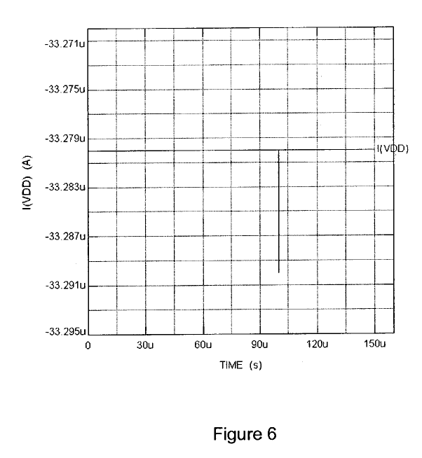

FIG. 6 illustrates a current signature of test circuit 24 with an overlap capacitance of 1 fF in the NMOS transistors and a gate to substrate short of 90 kΩ, which causes an increase in the supply current drawn by about 550 nA. Because the gate to substrate short in this instance is less than that in the preceding example, a larger shift in the value of the supply current drawn is observed.

As observed from FIGS. 4 to 6, the type of defect and the severity of the defect may be determined by the present invention. For example, the degree of overlap capacitance in the NMOS transistors is detected by the speed of the transient; a faster transient denotes a smaller overlap capacitance. Similarly, the magnitude of the shift in the value of the supply current drawn is indicative of the characteristics of a gate to substrate short.

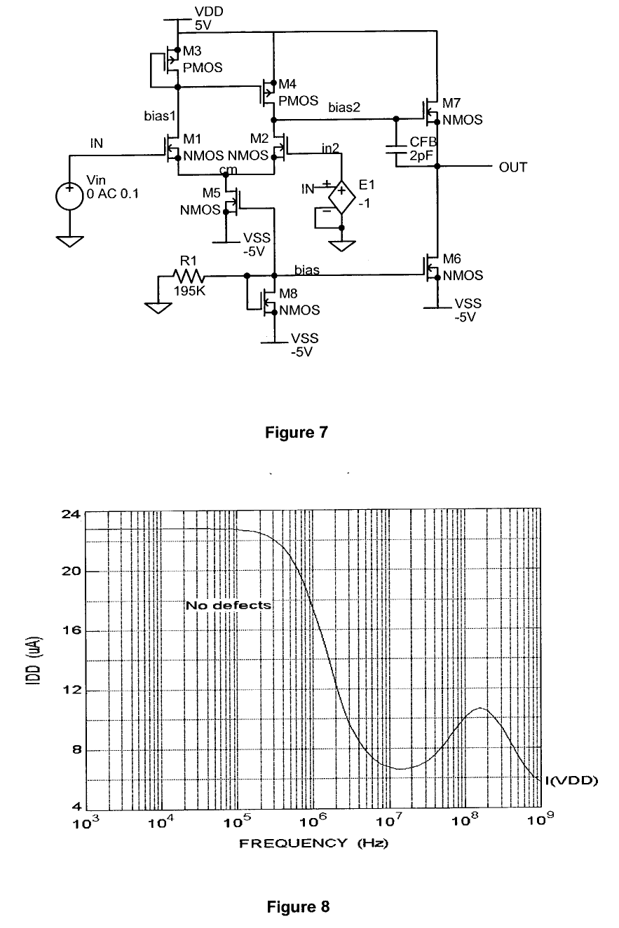

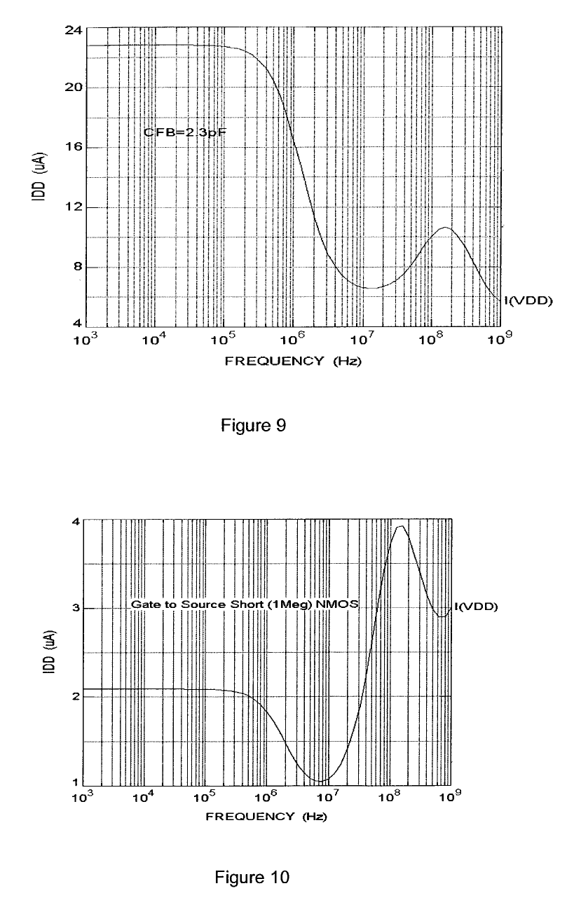

FIG. 7 illustrates a test circuit 28 for detecting a defect in a complementary metal-oxide semiconductor (CMOS) operational-amplifier circuit in accordance with one embodiment of the present invention. FIG. 8 illustrates an ideal current signature of test circuit 28 in accordance with one embodiment of the present invention. The ideal current signature is a current spectrum of a defect-free test circuit. FIGS. 9 to 12 illustrate examples of test supply current signatures of test circuit 28 in accordance with one embodiment of the present invention. The test supply current signatures are current spectrums of defective test circuits.

FIG. 9 illustrates a current signature of test circuit 28 with a change in output capacitor value. Specifically, the feedback capacitance (CFB) is set at 2.3 pF. Changes and defects in output capacitance are usually traced back to an undesirable change in processing conditions. In this example, a 15% change in capacitance value causes about a 2% leftward shift in the frequency domain of the current signature relative to the ideal current signature. Greater changes would result in greater shifts. The present invention is therefore able to identify the type of defect (change in output capacitance), but also the severity of the defect.

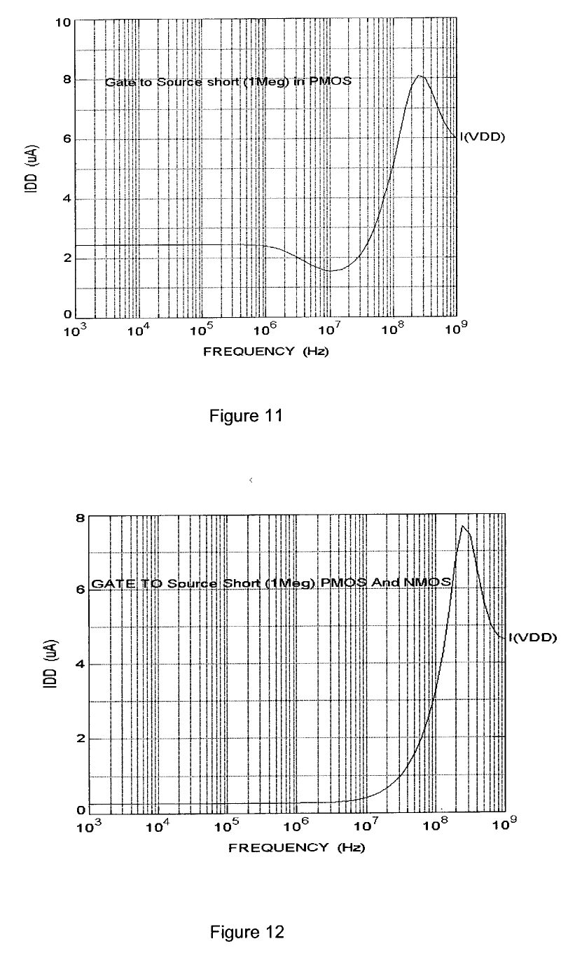

FIG. 10 illustrates a current signature of test circuit 28 with a gate to source short in a NMOS transistor. The defect, which shorts the gate and source, may be simulated by adding a 1 mega-ohm (MΩ) resistor. FIG. 11 illustrates a current signature of test circuit 28 with a gate to source short of 1 MΩ in a P type Metal-Oxide Semiconductor (PMOS) transistor. FIG. 12 illustrates a current signature of test circuit 28 with multiple defects, namely, a gate to source short of 1 MΩ in a PMOS transistor and a gate to source short of 1 MΩ in a NMOS transistor. In each of FIGS. 10-12, the simulated defects generate different spectrums for the current signatures.

As evident from FIGS. 2-12, each type of defect or group of defects in a test circuit generates a different current signature, which can be distinguished from an ideal current signature to detect a defect. Additionally, the current signatures may also be distinguished from the current signatures of other types of defects or groups of defects for defect identification. Another advantage of the invention is that system 10 may be applied to both digital test circuits and analog test circuits because it does not distinguish between the two types of circuits. In contrast, other defect detection systems such as measuring quiescent current are designed strictly for digital circuits.

Referring back to FIG. 1, processor 20 may be used to determine a reliability of semiconductor chip 12, that is, a probability that semiconductor chip 12 will perform in accordance with expectations for a predetermined period of time in a given environment. The reliability of a chip may be determined by using both fault and reliability models. Fault models predict circuit behavior in the presence of circuit defects. The predictions may be used in conjunction with reliability models, which are derived from statistical analysis of test data from the chip. Using the end user's requirements as a guideline as well as results from fault models, the reliability model is then used to determine whether the chip is reliable or not.

An example of the statistical analysis that occurs in a reliability model is defect distribution. For example, certain defects such as crystal originated particles (COP) have a uniform distribution. In contrast, particle types (excess material on the wafer or chip) follow a negative binomial distribution. Accordingly, statistical distributions of the types of defect present are preferably taken into account when determining the reliability of semiconductor chip 12.

The statistical distributions of the types of defect may be obtained from experimental data by taking measurements from a plurality of test circuits, each of which is preferably located on different sites in semiconductor wafer 14. Alternatively, independent statistical distributions may be supplied by individual semiconductor fabrication and packaging facilities, which may be able to provide their own data. The present invention may then provide data on the presence of defects, the type of defects present, the severity of the defects and the reliability of semiconductor chip 12 to a packaging department or a semiconductor chip fabrication plant.

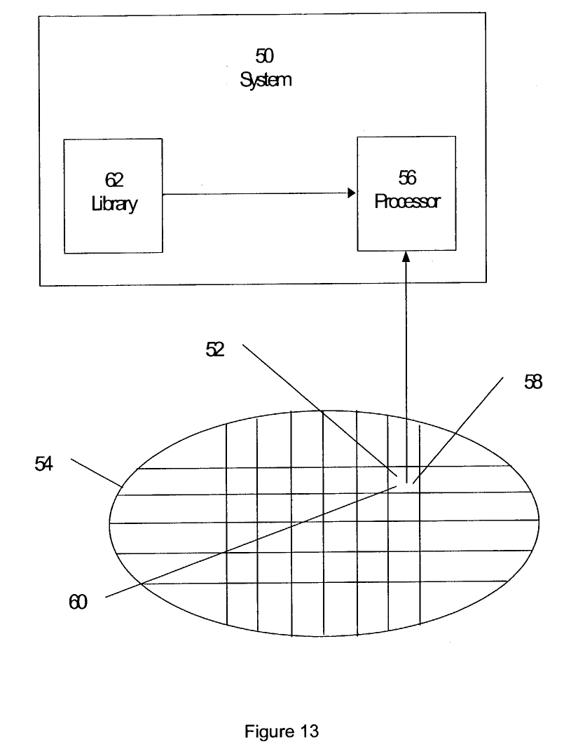

FIG. 13 illustrates a system 50 for testing a semiconductor chip 52 on a semiconductor wafer 54 in accordance with another embodiment of the present invention. System 10 includes a processor 56 to read a current signature of a test circuit 58 on semiconductor wafer 54 based on a supply current measured by a sensor 60 integrated within test circuit 58. Processor 56 compares the current signature of test circuit 58 with an ideal current signature from a library 62 to determine whether a defect is present in semiconductor chip 52. Additionally, processor 56 may be used for defect identification and reliability determination as discussed previously.

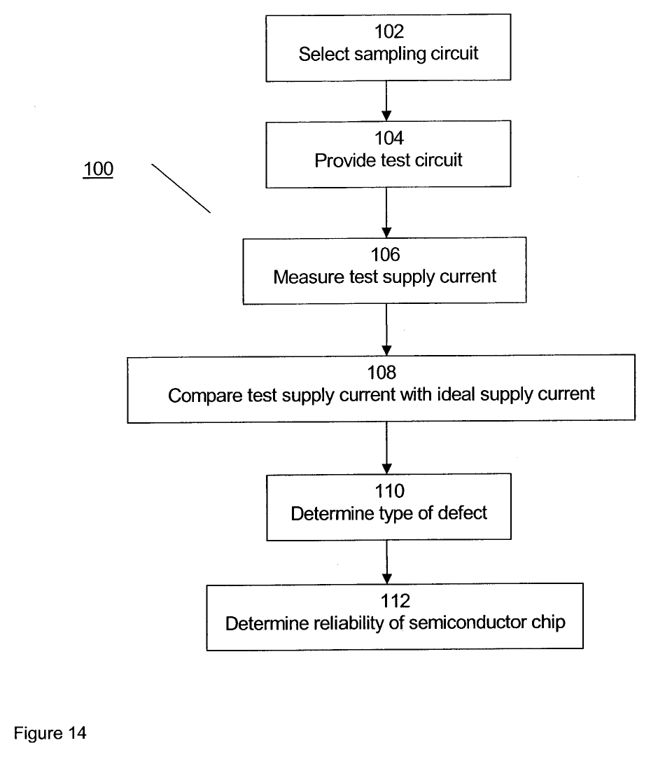

FIG. 14 illustrates a method 100 for testing a semiconductor chip on a semiconductor wafer in accordance with yet another embodiment of the present invention. A sampling circuit having an ideal supply current is selected in a block 102 and a test circuit is provided in a block 104 by fabricating the sampling circuit onto the semiconductor chip. A test supply current measured in a block 106 from the test circuit by a current sensor is compared in a block 108 with the ideal supply current to detect a defect in the semiconductor chip before the semiconductor chip is packaged.

The sampling circuit may be selected in block 102 from a library of sampling circuits based on a type of defect to be detected. The type of defect may be determined in a block 110 when the test supply current is compared with fault models for the sampling circuit and a match is obtained. Similarly, a reliability of the semiconductor chip may be determined in a block 112 by comparing the test supply current to a reliability model for the sampling circuit.

Other embodiments of the invention will be apparent to those skilled in the art from consideration of the specification and practice of the invention. Furthermore, certain terminology has been used for the purposes of descriptive clarity, and not to limit the present invention. The embodiments and preferred features described above should be considered exemplary, with the invention being defined by the appended claims.

1. A method for testing a semiconductor chip, comprising:
selecting a sampling circuit having an ideal supply current;
providing a test circuit by fabricating said sampling circuit onto said semiconductor chip;
measuring a test supply current from said test circuit; and
comparing said test supply current with the ideal supply current to detect a defect in said semiconductor chip.

2. A method for testing a semiconductor chip as recited in claim 1, wherein said sampling circuit is selected from a library of sampling circuits.

3. A method for testing a semiconductor chip as recited in claim 2, further comprising selecting said sampling circuit based on a type of defect to be detected.

4. A method for testing a semiconductor chip as recited in claim 3, wherein said test supply current is measured by a current sensor.

5. A method for testing a semiconductor chip as recited in claim 2, further comprising comparing said test supply current with a fault model for said sampling circuit to determine a type of defect.

6. A method for testing a semiconductor chip as recited in claim 5, wherein a reliability of said semiconductor chip is determined when said test supply current is compared to a reliability model for said sampling circuit.

7. A method for testing a semiconductor chip as recited in claim 1, wherein said defect is detected before said semiconductor chip is packaged.

8. A method for testing a semiconductor chip, comprising:
selecting a sampling circuit having an ideal supply current signature;
providing a test circuit by fabricating said sampling circuit onto said semiconductor chip;
measuring a test supply current from said test circuit, wherein said test supply current has a test current signature;
comparing said test current signature with the ideal current signature to identify a defect in said semiconductor chip.

9. A method for testing a semiconductor chip as recited in claim 8, wherein said sampling circuit is selected from a library of sampling circuits.

10. A method for testing a semiconductor chip as recited in claim 9, further comprising selecting said sampling circuit based on a type of defect to be detected.

11. A method for testing a semiconductor chip as recited in claim 10, wherein said test supply current is measured by a current sensor.

12. A method for testing a semiconductor chip as recited in claim 8, further comprising comparing said test supply current with a fault model for said sampling circuit to determine said type of defect.

13. A method for testing a semiconductor chip as recited in claim 12, wherein a reliability of said semiconductor chip is determined when said test supply current is compared to a reliability model for said sampling circuit.

14. A method for testing a semiconductor chip as recited in claim 13, wherein the defect is detected before the semiconductor chip is packaged.

15. A semiconductor chip testing system, comprising:
a sensor to measure a supply current from a test circuit on a semiconductor chip;
a sampling circuit library to store a number of sampling circuits; and
a processor coupled between said sensor and said library, wherein said processor is to detect a defect on said semiconductor chip by comparing said supply current with an ideal supply current from a selected sampling circuit.

16. A semiconductor chip testing system as recited in claim 15, wherein said selected sampling circuit is selected based on a selected defect to be detected.

17. A semiconductor chip testing system as recited in claim 15, further comprising a fault model library to store a number of fault models for each of said number of sampling circuits.

18. A semiconductor chip testing system as recited in claim 17, wherein said defect is detected by comparing said test supply current with a selected fault model from said fault model library.

19. A semiconductor chip testing system as recited in claim 18, further comprising a reliability model library to store a number of reliability models for each of said number of sampling circuits.

20. A semiconductor chip testing system as recited in claim 19, wherein a reliability standard of said semiconductor chip is determined by comparing said test supply current with a selected reliability model.
